(19) United States
(12) Patent Application Publication
(10) Pub. No.: US 2001/0018755 A1
(43) Pub. Date: Aug. 30, 2001

(54) Data conversion device for a reed-solomon decoder

(76) Inventors: Volker Zens, Denzlingen (DE); Franz-Otto Witte, Emmendingen (DE)

Correspondence Address: Patrick J. O'Shea, Esq., Samuels, Gauthier & Stevens, LLP, Suite 3300, 225 Franklin Street, Boston, MA, 02110, US

(21) Appl. No.: 09/740,734

(22) Filed: Dec. 18, 2000

(30) Foreign Application Priority Data
Dec. 17, 1999 (DE) 199 60 923.3-35

(51) Int. Cl. H03M 13/03

(52) U.S. Cl. 714/784; 714/795

(57) ABSTRACT

A data converter device for a Reed-Solomon decoder receives a first data stream (d1) and a second data stream (d2). The first data stream (d1) is input to the Reed-Solomon decoder, whose decoding process is defined by a first primitive polynomial, either directly or via a first intermediate processing stage. The second data stream (d2) is conducted to a code converter, either directly or via a second intermediate processing stage. The code converter performs an isomorphic imaging process. After the Reed-Solomon decoder a second isomorphic imaging process of these converted data, inverse to the first one, is performed by a second code converter.

### BACKGROUND OF THE INVENTION

The invention relates to a device for a Reed-Solomon decoder, which is fed in time multiplex operation from a data source with a first and second data stream whose data correspond to a first and second Reed-Solomon code, respectively.

Reed-Solomon encoded data streams are increasingly being used for the digital transmission of audio or video signals. Besides the coding of the actual signal content, which is transmitted in time multiplex operation together with other signals, information must also be transmitted that is used to find and decode the desired signal within the received data stream. For data protection, the signal data, linked together in time multiplex operation, are converted on the transmitter side block-by-block in accordance with the first Reed-Solomon code, while the control information is converted in accordance with the second Reed-Solomon code. These encoded streams form the first and second data streams. As known, a Reed-Solomon code is a forward error correcting code that mitigates the effects of bit error bursts in a received signal stream. These two data streams are transmitted serially in time multiplex operation. The format in which these data streams are transmitted contains in its header the second data stream with the channel and control information, and in a following data block the first data stream with the signal contents. In some applications, the first data stream is called the “broadcast channel” (BC) and the second data stream is often called the “time slot control channel” (TSCC); however, this special terminology will not be used in the following description. Through this specified arrangement, the two data streams can again easily be separated on the receiver side. They are subsequently processed at different speeds, depending on whether the first or second data stream is being processed. In the second data stream all the successive data are important and consequently they all must be detected and processed. Although the first data stream has the same data rate as the second data stream, not all the successive data or data words need to be detected and processed, but only those that are relevant for the channel that is being received. With a plurality of channels, which are being transmitted in time multiplex operation, a relevant data word is followed by a large number of irrelevant data words. Therefore, the required processing speed is reduced in the corresponding proportion.

Different codes according to the Reed-Solomon method generally differ in that the associated finite bodies, which are also called Galois fields, are defined by different primitive polynomials, and the different parameters of the code generating polynomials are defined. The principle of coding and decoding such Reed-Solomon codes is not the subject of this invention. Both are known and are extensively described in the relevant technical literature. For example, see “Theory and Practice of Error Control Codes”, Richard E. Blahut, Addison-Wesley Publishing Company, Inc., 1983, ISBN 0-201-10102-5, and “Channel Coding”, Martin Bossert, B. G. Teubner, Stuttgart, Germany, 1992, ISBN 3-519-06143-0. Additional security against transmission errors may also achieved by forward-directed error correction according to Viterbi.

Two independent Reed-Solomon decoders are needed to process two data streams based on different Reed-Solomon codes. Correspondingly, another Reed-Solomon decoder is needed for every additional data stream. Due to the high data rate of the data that must be processed in real time operation, important parts of the two Reed-Solomon decoders are implemented as hardware circuits in a specially designed Galois field processor, because a corresponding subprogram is not fast enough in conventional universal processors. One of the central functional blocks is a multiplier that multiplies two polynomials in parallel. The desired signal resolution determines the word width, and the latter determines the order of the associated Galois field. Beyond a seven order Galois field, such parallel multipliers become extremely complex, because the 7×7 logical operations corresponding to the word width of seven (7) bits must be performed simultaneously. This involves a special multiplier, which, in a kind of modulo operation, again and again forms as the resulting elements of the multiplication only elements of the finite field. The array of these multipliers is thereby simplified compared to the array of a normal parallel multiplier. The logical linkages of the individual partial products of this modulo operation correspond to the “exclusive or”-linkage (XOR) and the logical “and”-linkage (AND). Despite this simplification, the modulo multiplier constitutes considerable complexity within the Galois field processor.

Therefore, there is a need for a simplified data conversion device that can decode in real-time at least two data streams that have been converted with different Reed-Solomon codes.

### SUMMARY OF THE INVENTION

Briefly, according to an aspect of the present invention, a data conversion device for a Reed-Solomon decoder that is fed by a first and second data stream (d1, d2), and the first data stream (d1) is conducted to the Reed-Solomon decoder, whose decoding process is defined by a first primitive polynomial, either directly or via an intermediate processing stage. The second data stream (d2) is conducted to a code converter either directly or via an intermediate processing stage. The code converter performs an isomorphic imaging process. After the Reed-Solomon decoder, a second isomorphic imaging process of these converted data, inverse to the first one, is performed by a second code converter.

The present invention utilizes the isomorphic imaging properties of Galois fields of the same order for the Reed-Solomon decoding of one data stream. This is possible if the two fields are defined by different primitive polynomials of the same degree. Advantageously, through this transformation only a single Reed-Solomon decoder is needed for both data streams. A control device sets the different parameters in the single Galois field processor for the respective generator polynomials. Of course, more data streams can also be imaged isomorphically in the same manner and can be decoded accordingly, as long as their Galois fields have the same order as the first two Galois fields.

These and other objects, features and advantages of the present invention will become more apparent in light of the following detailed description of preferred embodiments thereof, as illustrated in the accompanying drawings.

### BRIEF DESCRIPTION OF THE DRAWING

FIG. 1 is a block diagram illustration of a Reed-Solomon decoder incorporating the present invention;

FIG. 2 illustrates a derivation of the elements of a first primitive polynomial;

FIG. 3 illustrates a derivation of the elements of a second primitive polynomial; and

FIG. 4 illustrates in tabular form a search for solutions for the isomorphic image.

### DETAILED DESCRIPTION OF THE INVENTION

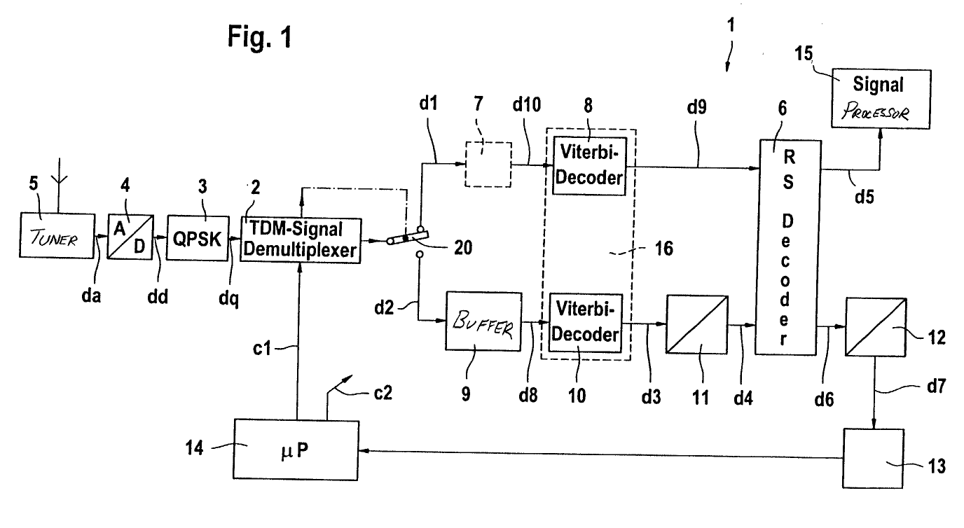

FIG. 1 is a block diagram illustration of a device 1 for a Reed-Solomon decoder within a Galois field (GF) field processor that decodes two different Reed-Solomon-coded data streams d1, d2. A source 2 for the two data streams d1, d2 is, for example, a time division multiplexed (TDM) signal demultiplexer. The TDM demultiplexer 2 receives a data stream dq from a quadrature phase shift keying (QPSK) demodulator 3 with a prescribed data format. The QPSK demodulator 3 receives a digitized signal dd from an analog-to-digital converter (ADC) 4 indicative of a tuner output signal da. To ensure proper sampling according to the Nyquist criteria, the sampling rate of the ADC 4 is at least twice the symbol rate. For example, for a symbol frequency of 4 MHz, an ADC clock pulse frequency of at least 8 MHz is required, and the resolution should comprise at least 32 stages (i.e., five (5) bits).

An electronic switch 20 filters the first and second data streams d1, d2 from the data stream dq. For the first data stream d1, the TDM-signal demultiplexer 2 picks out from the channel-wise transmitted information in the data area of the data stream dq only data associated with the desired channel. The QPSK demodulator 3 determines the phase quadrant (out of the four possible quadrants) in which the received signal dd lies. The associated symbols, whose data contain the digital TDM signal in the form of a continuous data stream dq are then determined from the quadrant assignment. The circuit blocks of the GF processor include a Reed-Solomon (RS) decoder 6 as an essential unit for the first and second data stream d1, d2. An intermediate processing stage 7, 8 for the first data stream d1 is situated in the signal flow path before the RS decoder 6. An intermediate processing stage 9, 10 and a first code converter 11 for the second data stream d2 are located upstream of the RS decoder 6. The first code converter 11 isomorphically converts its input data stream d3 into a data stream d4 that is input to the RS decoder 6. An inverse, likewise isomorphic, imaging of the data stream d6 in a code converter 12, following the Reed-Solomon decoder, corresponds to the isomorphic imaging before the Reed-Solomon decoder 6. This again reverses the isomorphic imaging process, after the Reed-Solomon decoding has taken place. The associated data stream d7 is stored in a static memory 13. This preferably is part of a control device 14 which, in dependence on these data, generates control instructions c1, c2 for the entire arrangement and also prescribes the specific parameters dr of the generator polynomials in the Reed-Solomon decoder. The control device 14 preferably is a co-integrated micro-controller (C), so that the control instructions c1, c2, which depend on the first data stream d1, will be available, if possible, without delay. This is especially important for setting the selection parameters in the TDM-signal demultiplexer 2, which must filter the relevant data for the first and second data stream d1, d2 out of the QPSK demodulator output stream dq. The output data stream d5 of the Reed-Solomon decoder 6, which contains the actual information (e.g., the BC signal), is conducted through a signal processor 15 that is connected to other circuit components (e.g., amplifiers and reproduction devices not shown in FIG. 1).

The first and second intermediate processing stages 7, 8 and 9, 10 respectively, may include time equalization stages or buffer devices 7, 9 for the respective data streams d1, d2. If the first and second data streams d1, d2 additionally are coded according to the Viterbi method, a Viterbi decoding process is performed in the first and second intermediate processing stage by a first and second Viterbi decoder 8, 10. This likewise requires circuits for time equalization or buffering. Since Viterbi decoders contain extensive circuitry, and since the second data stream d2 must be processed first in every data block to obtain the subsequent control signals c1, c2, using only a single Viterbi decoder 16 for the two data streams d1, d2 lessens the circuitry and surface requirements for the monolithic integration. To match the relatively fast data stream d2 to a relatively slow Viterbi decoder 10 or 16, the embodiment of FIG. 1 includes a buffer device 9 in the form of a first-in-first-out (FIFO) memory, which forms the slower and thus matched data stream d8.

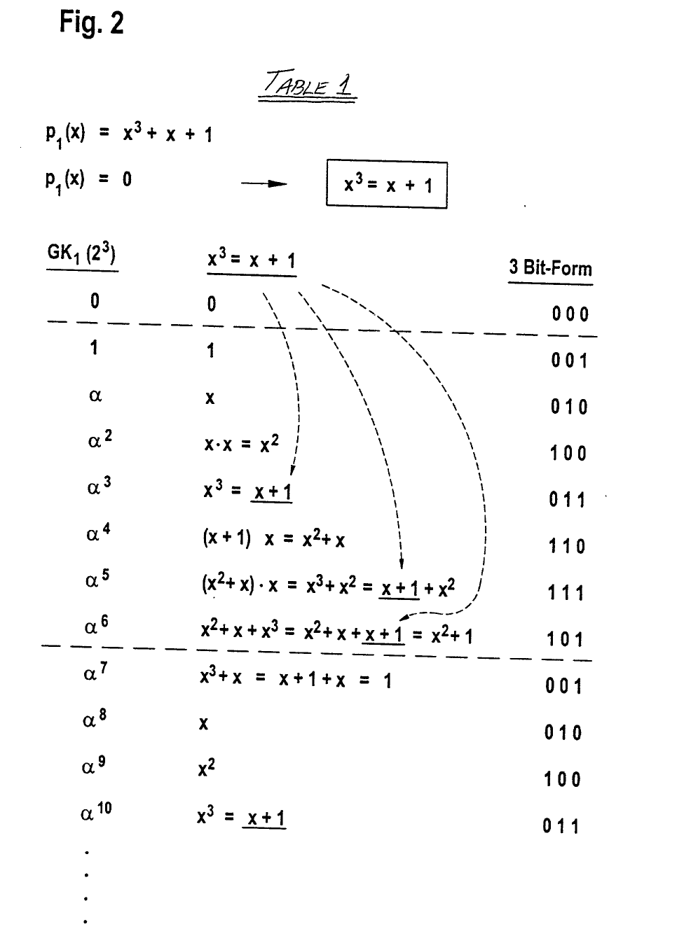

As an explanatory example, FIG. 2 shows in tabular form the derivation of the elements of a first primitive polynomial of third order p₁(x)=x³+x+1. The various elements of the associated Galois field of third order are formed by setting the first primitive polynomial p₁(x)=0. From this follows that the primitive element of the Galois field is defined by the relation x³=x+1. Inserting “0”, “1” or “α¹” into this equation yields the individual elements. Because the Galois field is finite, these elements repeat periodically in the same sequence. Since the individual elements of the Galois field are usually processed as binary data by the electronic conversion circuitry, a binary notation for the individual elements of the particular Galois field is appropriate, such that the binary notation depends on the individual values of x of the primitive polynomial. For a third order Galois field, all the elements can be represented by a 3-digit binary number. One also calculates with these binary numbers in the sense of an EXOR logic, for example in the Galois parallel multiplier. The abbreviated notation GF(2ⁿ), where “n” designates the order, thus stands for the entire Galois field. This also has the advantage that it immediately shows the number of different elements. With a third order Galois field GF(2³), there are, besides the null element “000”, seven different elements. The logical modulo operations in the Reed-Solomon decoder 6 (FIG. 1) never leave the domain of these seven elements.

The left column “GF₁(2³)” of the table set forth in FIG. 2 shows, as ascending powers α¹, successive elements of the primitive polynomial p₁(x)=x³+x+1. The middle column “x³=x+1” shows the associated formation equations that are based on EXOR linkages. The right column “3-bit form” shows the three bits of the Galois element that is processed as a data word in the Reed-Solomon decoder 6. For the sake of clarity, in the middle column those parts of the equations are underlined that derive from setting the polynomial equal to zero, with p₁(x)=0, namely x³=x+1. Although the individual elements, ascending from zero, become larger corresponding to the powers of α, the right column, with elements in binary representation, does not show these constantly ascending values in the sense of the usual powers of 2. Deviations obtain after “010”, “110”, “110”, “011”, and “110”. But this is okay since this 3-digit data format does not involve binary numbers and their associated values, but only a data-like association with the individual elements. After the last element “110” of the Galois field GF₁(2³), the next element in the sense of the modulo operation again is the first element “001”, with the null element “000” forming a special element that is always omitted.

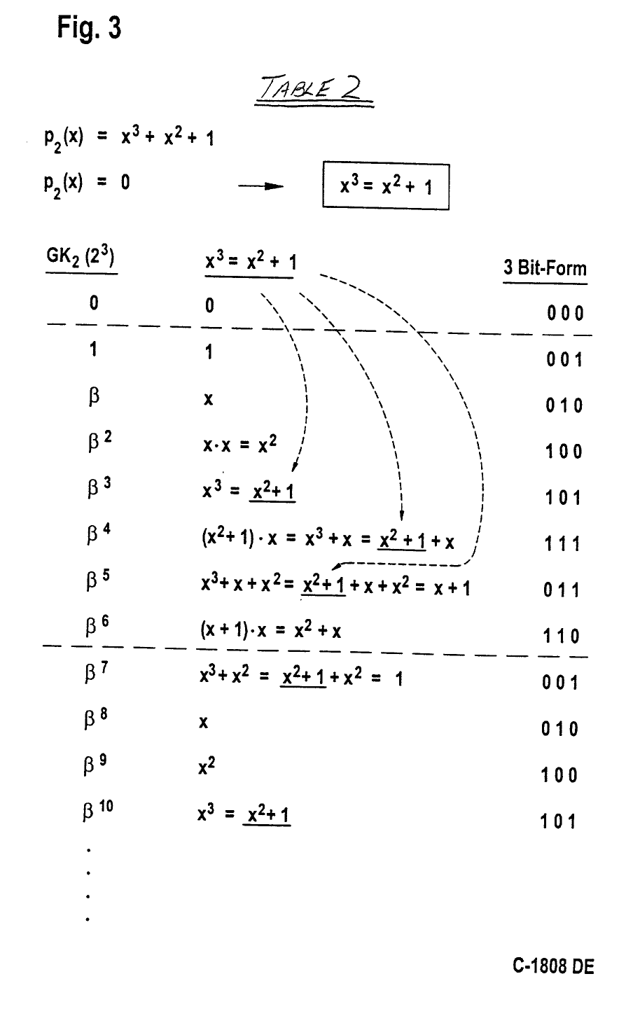

Table 2 of FIG. 3 illustrates the individual elements as ascending powers β¹ of a second Galois field of third order GF₂(2³). The primitive polynomial p₂(x) to form these elements is p₂(x)=x³+x²+1. The structure of Table 2, with the three columns “GF₂(2³)”, “x³=x²+1”, and “3-bit form” corresponds to the structure of Table 1, so that there is no need to repeat the description. Each of the seven elements has a data word assigned to it in binary 3-bit format. As in Table 1, however, these data words do not correspond to ascending binary numbers. The other primitive polynomial p₂(x) also changes the sequence of data words compared to that of Table 1.

An isomorphic image converts the elements of a finite field into the elements of another finite field of the same order. For the inventive code converters 11, 12 (FIG. 1), this can be performed for example, by way of a tabular association, if the conversion is known. The mode or procedure for finding the correct conversion will be explained in terms of a simple example, using the present Tables 1 and 2. In the isomorphic imaging process, the element α¹ of one Galois field is determined first, which yields the value zero when it is inserted in the primitive polynomial of the other Galois field and thus by definition there forms the primitive element β¹ of this Galois field. Powers of the primitive element found in this way yield only elements of this second Galois field. This idea provides a way for finding the individual associations for the isomorphic imaging of a given Galois field. In the example used here, this is relatively easy since the Galois field has only seven elements that can easily be inserted into the primitive polynomial of the other Galois field. If the number of elements is large (e.g., a Galois field of seventh order), such an insertion is no longer possible manually. This successive sampling can be done easily and automatically by a computer using suitable programs. If such sampling finds several elements that yield the value zero when inserted into the primitive polynomial, then each of these solutions can serve as a primitive element for an associated isomorphic image. However, not all solutions are equivalent from the perspective of the particular application. The optimal solution can be found through a simulation of the Reed-Solomon decoding process.

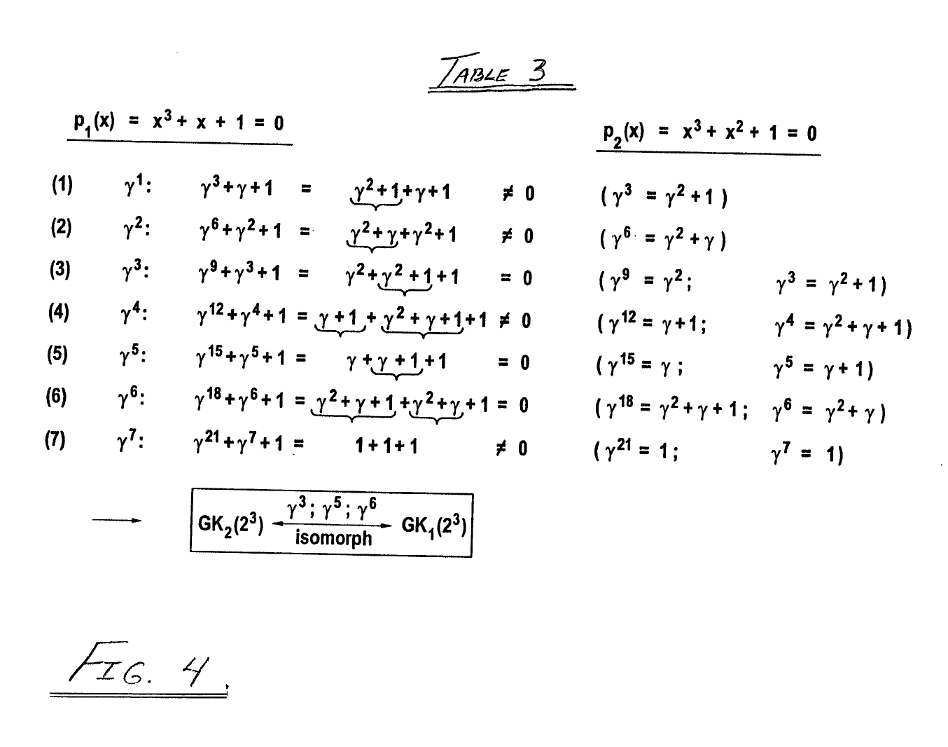

Table 3 of FIG. 4 shows an example of such successive insertion of the seven elements γ¹ to γ⁷ of the second primitive polynomial p₂(x)=x³+x²+1 into the first primitive polynomial p₁(x)=x³+x+1, to find the elements for which the first primitive polynomial becomes zero. The test elements γ are ordered in rows by ascending powers γ¹. The third, fifth, and sixth rows, with the primitive elements γ³, γ⁵ and γ⁶ always yield the value zero upon insertion into the first primitive polynomial p₁(x)=x³+x+1. These elements γ³, γ⁵ and γ⁶ thus each represent a primitive element. It should be pointed out that, in the calculation of the first primitive polynomial p₁(x), the multiples and powers of γ involve multiplications, and the “+” sign involves XOR linkages.

To obtain the association between the elements of the second primitive polynomial and the first primitive polynomial, and thus the image of GF₂ on GF₁ and also the inverse image of GF₁ on GF₂, the associated residual classes must first be formed in accordance with the solutions γ³, γ⁵ and γ⁶. By the function residual class is meant the modulo division of the particular primitive polynomial, the remainder of this division being the result. For every modulo division, the associated exponent of the element must be multiplied in correspondence with the exponent i of the particular solution γ. In the present example with γ³, the exponent of the solution is 3. Since GF(2³) (i.e., a third order GF) has seven different primitive elements, the value 7 is normative for the modulo division. The notation for this modulo division is different, “mod(x, y)” or “x mod”, that means, for example with x=18 and y=7, the division 18/7=2+4/7. In this division example, 4 is the remainder that can no longer be divided by 7, and consequently the solution of the modulo division. In the notation given above, this then looks as follows: 18 mod 7=4.

The seven elements of the desired GF(2³), which up to now have not been found, are formally listed in the following table T(GF(2³)). The exponents i of the powers δⁱ here ascend from i=0 to i=6. Due to the finite number of elements in a third order Galois field—as already specified, there are seven different elements,—the exponents i=7 and i=0 yield the same element δ⁰. “δ” designates the primitive element of an arbitrary Galois field of third order. The associated elements δⁱ, with i ascending from i=0 to i=6, are then obtained as table T(δⁱ):

T(δⁱ): { δ⁰, δ¹, δ², δ³, δ⁴, δ⁵, δ⁶}

In simplified notation, using only the exponents i of the table T(δⁱ), the successive seven elements of an arbitrary third order Galois field can be represented in the following generalized tabular form:

T(GF(2³)): {0, 1, 2, 3, 4, 5, 6}

The transformations are now performed from this table, by forming the residual classes with the found solutions of γ³, γ⁵ and γ⁶.

A detailed example shows the transformation of all the field elements (i) of the above-specified table T(GF(2³)): {0, 1, 2, 3, 4, 5, 6} for the solution γ³.

| | | |
|---|---|---|
| i = 0: mod(1·3, 7) = mod(0, 7) = 0 | in 3-bit format (compare | 001 |
| | Table 2): | |
| i = 1: mod(1·3, 7) = mod(3, 7) = 3 | in 3-bit format (compare | 011 |
| | Table 2): | |
| i = 2: mod(2·3, 7) = mod(6, 7) = 6 | in 3-bit format (compare | 101 |
| | Table 2): | |
| i = 3: mod(3·3, 7) = mod(9, 7) = 2 | in 3-bit format (compare | 100 |
| | Table 2): | |
| i = 4: mod(4·3, 7) = mod(12, 7) = 5 | in 3-bit format (compare | 111 |
| | Table 2): | |
| i = 5: mod(5·3, 7) = mod(15, 7) = 1 | in 3-bit format (compare | 010 |
| | Table 2): | |
| i = 6: mod(6·3, 7) = mod(18, 7) = 4 | in 3-bit format (compare | 110 |
| | Table 2): | |
| i = 7: mod(7·3, 7) = mod(21, 7) = 0 | (since 7 mod 7 =0) | 001 |
| | (compare Table 2): | |
| i = 8: mod(8·3, 7) = mod(24, 7) = 3 | (since 7 mod 7 =0) | 011 |
| | (compare Table 2): | |
| i = 9: mod(9·3, 7) = mod(27, 7) = 6 | (since 7 mod 7 =0) | 101 |
| | (compare Table 2): | |

Beginning with i=7, the field elements repeat. The table of field elements belonging to the solution γ³, that is the associated transformation table, is T1(γ³): {0, 3, 6, 2, 5, 1, 4}.

For the three solutions γ³, γ⁵ and γ⁶ there thus are the following three transformation tables, which are formed in the same manner through the modulo division described above:

T1(γ³): {0, 3, 6, 2, 5, 1, 4}

T2(γ⁵): {0, 5, 3, 1, 6, 4, 2}

T3(γ⁶): {0, 6, 5, 4, 3, 2, 1}

The inverse transformation of the table T1(γ³): {0, 3, 6, 2, 5, 1, 4} with γ³, γ⁵ and γ⁶, through the modulo division, yields the three following inverse transformation tables:

T4(γ³): {0, 2, 4, 6, 1, 3, 5}

T5(γ⁵): {0, 1, 2, 3, 4, 5, 6}

T6(γ⁶): {0, 4, 1, 5, 2, 6, 3}

Only the inverse transformation table T5(γ⁵): {0, 1, 2, 3, 4, 5, 6}, which was inverse transformed with γ⁵, again yields the original field elements T(GF(2³)): {0, 1, 2, 3, 4, 5, 6}. The imaging prescription γ⁵ holds for the transformation in one direction, and the imaging prescription γ⁵ holds for the inverse transformation. It does not matter here in what direction the back and forth transformation between the first and second Galois field is performed. That is, if the forward transformation of GF₁(2³) to GF₂(2³) or from GF₂(2³) to GF₁(2³) is performed according to the imaging prescription γ³, the inverse transformation from GF₂(2³) to GF₂(2³), or from GF₁(2³) to GF₂(2³) must be performed according to the imaging prescription γ⁵.

In similar fashion, it can be shown that the inverse transformation of the second transformation table T2(γ⁵): {0, 5, 3, 1, 6, 4, 2} with γ³, γ⁵ and γ⁶ as field elements yields the following inverse transformation tables:

T7(γ³): {0, 1, 2, 3, 4, 5, 6}

T8(γ⁵): {0, 4, 1, 5, 2, 6, 3}

T9(γ⁶): {0, 2, 4, 6, 1, 3, 5}

Only the inverse transformation table T7(γ³): {0, 1, 2, 3, 4, 5, 6}, which was inverse transformed with γ³, again yields the original field elements T(GF(2³)): {0, 1, 2, 3, 4, 5, 6}. The forward transformation is performed through the imaging prescription γ⁵ and the inverse transformation through the imaging prescription γ³.

The inverse transformation of the third transformation table T3(γ⁶): {0, 6, 5, 4, 3, 2, 1} with γ³, γ⁵ and γ⁶ yields the following inverse transformation tables as field elements:

T10(γ³): {0, 4, 1, 5, 2, 6, 3}

T11(γ⁵): {0, 2, 4, 6, 1, 3, 5}

T12(γ⁶): {0, 1, 2, 3, 4, 5, 6}

Only the inverse transformation table T12(γ⁶): {0, 1, 2, 3, 4, 5, 6}, which was inverse transformed with γ⁶, again yields the original field elements T(GF(2³)): {0, 1, 2, 3, 4, 5, 6}. In the case of this transformation, the forward and inverse transformations are performed with the same imaging prescription γ⁶.

The forward and inverse transformation of the individual elements can be represented in simplified fashion by a residual class table Tr. With the imaging prescription γ³ for the forward transformation and the three field elements i=0, 1, 2, the following residual class table Tr1 is obtained, due to the third order of the two Galois fields GF₁(2³) and GF₂(2³):

Tr1: {1, 1+x+x², 1+x} in polynomial form

Tr1: {001 111 011} in 3-bit format.

Another notation for the 3-bit format of Tr1 is a 3x3 matrix form:

$$\vert \begin{matrix}0 & 0 & 1 \\ 1 & 1 & 1 \\ 0 & 1 & 1\end{matrix} \vert$$

In similar fashion the inverse transformation with the imaging prescription γ³ and the three field elements i=0, 1, 2, yields the residual class table Tr2:

Tr2: {1, 1+x+x², 1+x} in polynomial form

Tr2: {001 101 110} in 3-bit format.

Another notation for the 3-bit format of Tr2 is a 3x3 matrix:

$$\vert \begin{matrix}0 & 0 & 1 \\ 1 & 0 & 1 \\ 1 & 1 & 0\end{matrix} \vert$$

Compared to the 42-bits of the direct tabular representation for the seven primitive elements, each with 3 bits, and the associated seven addresses, each likewise with 3 bits, this involves only 9 bits that need to be stored for a transformation. This matrix representation of the isomorphic image, using as an example a first and second Galois field of third order, shows that the image can be realized in this manner very simply in a GF processor, and requires little memory and computation there. With Galois fields of higher order, the savings effect resulting from the matrix representation is still greater.

Although the present invention has been shown and described with respect to several preferred embodiments thereof, various changes, omissions and additions to the form and detail thereof, may be made therein, without departing from the spirit and scope of the invention.

What is claimed is:

1. A data conversion device for a Reed-Solomon decoder, which is fed with at least a first and a second data stream from a data source in time multiplex operation, the data of said data streams corresponding respectively to a first and second Reed-Solomon code, with an associated first and second primitive polynomial different from one another but of the same order, said device comprising:
a first intermediate processing stage that receives the first data stream (d1) and provides a ninth data stream (d9) to a Reed-Solomon decoder whose decoding process is defined by the first primitive polynomial and at least a first generator polynomial;
a second intermediate processing stage that receives the second data stream (d2) and provides a third data stream (d3) to a first code converter (11) that performs an isomorphic imaging process of the data associated with the second primitive polynomial into data which are associated with the first primitive polynomial, wherein said first code converter provides a fourth data stream (d4) output signal that is input to said Reed-Solomon decoder; and
wherein said Reed-Solomon decoder selectively provides as an output signal one of a fifth data stream (d5) and a sixth data stream (d6); and
a second code converter that performs an isomorphic imaging process inverse to said first code converter, and converts said sixth data stream (d6) into a seventh data stream (d7) whose primitive polynomial is the second primitive polynomial.

2. The device of claim 1, wherein said first and second intermediate processing stages each include a Viterbi decoder.

3. The device of claim 1, wherein:
a single Viterbi decoder is present for said first and second intermediate processing stages;
in the first operating mode, the single Viterbi decoder is fed by the first data stream (d1) or by a tenth data stream (d10) depending on it, and its output is connected directly to the input of said Reed-Solomon decoder; and
in the second operating mode, said single Viterbi decoder is fed by an eighth data stream (d8), which depends on the second data stream (d2), and its output is connected, via said first code converter to the input of said Reed-Solomon decoder.

4. The device of claim 2 wherein said second intermediate processing stage comprises a buffer device that receives said second data stream and provides a buffered eight data stream (d8) to said Viterbi decoder.

5. The device of claim 1, wherein said first and second code converters include a stored table or a subprogram to convert the data.

6. The device of claim 5, wherein the data of the seventh data stream (d7) which controls said first and second operating modes through a control device, are stored in said device in a static memory.

7. The device of claim 1, further comprising a signal processor that receives and processes said fifth data stream (d5).

8. A data conversion device for a Reed-Solomon decoder that receives a first and a second data stream that correspond to a first and second Reed-Solomon code respectively with an associated first and second primitive polynomial different from one another but of the same order, said device comprising:
means for receiving and processing the first data stream (d1), and for providing a ninth data stream (d9) to a Reed-Solomon decoder whose decoding process is defined by the first primitive polynomial and at least a first generator polynomial;
means for receiving and processing the second data stream (d2), and for providing a third data stream (d3) to a first code converter that performs an isomorphic imaging process of the data associated with the second primitive polynomial into data which are associated with the first primitive polynomial, wherein said first code converter provides a fourth data stream (d4) output signal that is input to said Reed-Solomon decoder; and
wherein said Reed-Solomon decoder selectively provides as an output signal one of a fifth data stream (d5) and a sixth data stream (d6); and
means for performing an isomorphic imaging process that is inverse to said first code converter, and for converting said sixth data stream (d6) to a seventh data stream (d7) whose primitive polynomial is the second primitive polynomial.
